(19) United States
(12) Patent Application Publication
(10) Pub. No.: US 2025/0006866 A1
(43) Pub. Date: Jan. 2, 2025

(54) OPTICAL PANEL

(71) Applicant: AUO Corporation, Hsinchu (TW)

(72) Inventors: Min-Zi Hong, Hsinchu (TW); Cheng-He Ruan, Hsinchu (TW); Chun-Lung Huang, Hsinchu (TW)

(73) Assignee: AUO Corporation, Hsinchu (TW)

(21) Appl. No.: 18/755,690

(22) Filed: Jun. 27, 2024

(30) Foreign Application Priority Data
Jun. 29, 2023 (TW) 112124191

(51) Int. Cl. H01L 33/42; H01L 33/62

(52) U.S. Cl. CPC H01L 33/42; H01L 33/62

(57) ABSTRACT

An optical panel includes a first substrate, a second substrate, and a display medium layer. The first substrate includes a first carrier having active and peripheral areas, a first metal wire pattern extending from the peripheral area to a central portion of the active area, a first insulating layer, and a first transparent electrode. The first insulating layer is located on the first carrier and the first metal wire pattern and has a first through hole overlapping the central portion. A portion of the first metal wire pattern is located below the first through hole. The first transparent electrode overlaps the active area entirely and is electrically connected to the first metal wire pattern. The second substrate has a second carrier and a second transparent electrode overlapping the first transparent electrode. The display medium layer is located between the first transparent electrode and the second transparent electrode.

### CROSS-REFERENCE TO RELATED APPLICATION

This application claims the priority benefit of Taiwan application serial no. 112124191, filed on Jun. 29, 2023. The entirety of the above-mentioned patent application is hereby incorporated by reference herein and made a part of specification.

### BACKGROUND

### Technical Field

The disclosure relates to an optical panel.

### Description of Related Art

Transparent display panels are a new type of display devices. The main feature is that users can not only see the image displayed on a transparent display panel, but can also see the background objects through the display at the same time. Improved user experience is therefore provided.

Generally, a transparent display panel uses an array of light-emitting diodes to display images and is provided with a transmissive area around the light-emitting diodes that allows light to be transmitted. However, an image displayed by the transparent display panel can be easily affected by the transmitted light. To be specific, if the light from the back surface of the transparent display panel is excessively strong, the light may interfere with the image displayed on the transparent display panel. The user cannot view the image displayed on the transparent display panel clearly as a result.

### SUMMARY

The disclosure provides an optical panel including a first substrate, a second substrate, and a display medium layer. The first substrate includes a first carrier, a first metal wire pattern, a first insulating layer, and a first transparent electrode. The first carrier has an active area and a peripheral area located on at least one side of the active area. The first metal wire pattern is located on the first carrier and extends from the peripheral area to a central portion of the active area. The first insulating layer is located on the first carrier and the first metal wire pattern and has a first through hole overlapping the central portion of the active area. A portion of the first metal wire pattern is located below the first through hole. The first transparent electrode is located on the first insulating layer and overlaps the active area entirely. The first transparent electrode is electrically connected to the first metal wire pattern. The second substrate has a second carrier and a second transparent electrode. The second transparent electrode is located between the second carrier and the first carrier and overlaps the first transparent electrode. The display medium layer is located between the first transparent electrode and the second transparent electrode.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of an optical panel according to an embodiment of the disclosure.

FIG. 2A is a schematic top view of a substrate according to an embodiment of the disclosure.

FIG. 2B is a cross-sectional schematic view taken long cross-sectional lines A-A′ and in B-B′ in FIG. 2A.

FIG. 3A is a schematic top view of an optical panel according to an embodiment of the disclosure.

FIG. 3B is a schematic top view of a substrate according to an embodiment of the disclosure.

FIG. 3C is a cross-sectional schematic view taken long a cross-sectional line C-C′ in FIG. 3B.

FIG. 4A is a schematic top view of a substrate according to an embodiment of the disclosure.

FIG. 4B is a cross-sectional schematic view taken long cross-sectional lines A-A′ and in B-B′ in FIG. 4A.

FIG. 5 is a graph of transmittance versus time of an optical panel according to some embodiments of the disclosure.

FIG. 6A is a schematic top view of a substrate according to an embodiment of the disclosure.

FIG. 6B is a partially enlarged schematic view of the substrate of FIG. 6A.

FIG. 7 is a schematic top view of a metal mesh design method according to an embodiment of the disclosure.

FIG. 8A is a schematic top view of a substrate according to a comparative example of the disclosure.

FIG. 8B is a graph of voltage distribution of a transparent electrode of the substrate of FIG. 8A.

FIG. 9A is a schematic cross-sectional view of an optical panel according to an embodiment of the disclosure.

FIG. 9B is a schematic top view of a transmissive display panel of FIG. 9A.

### DESCRIPTION OF THE EMBODIMENTS

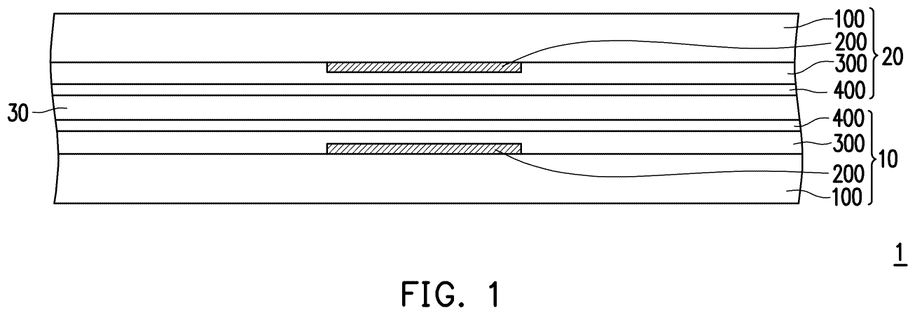

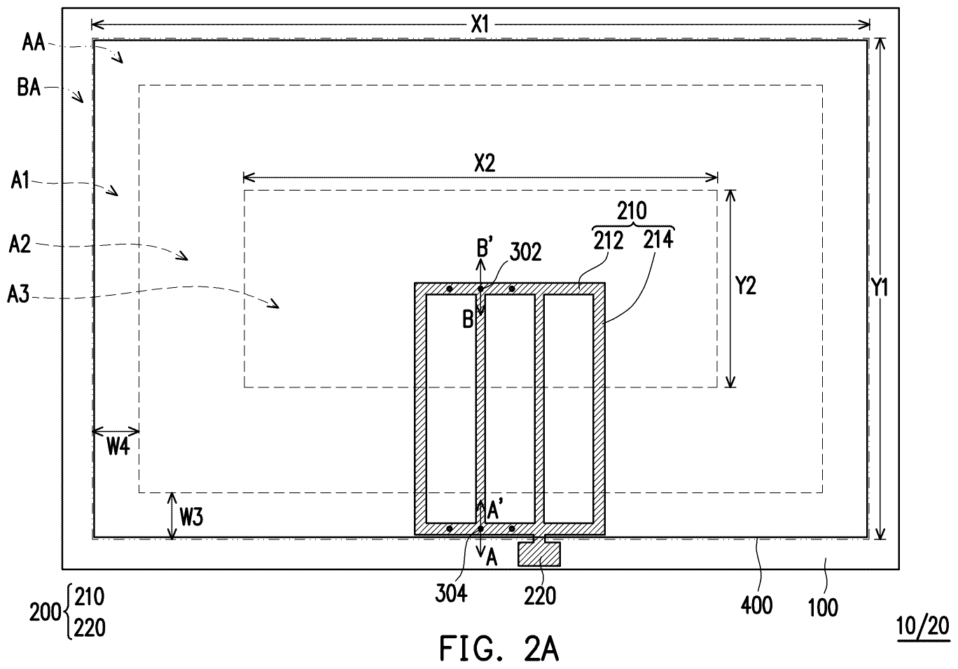

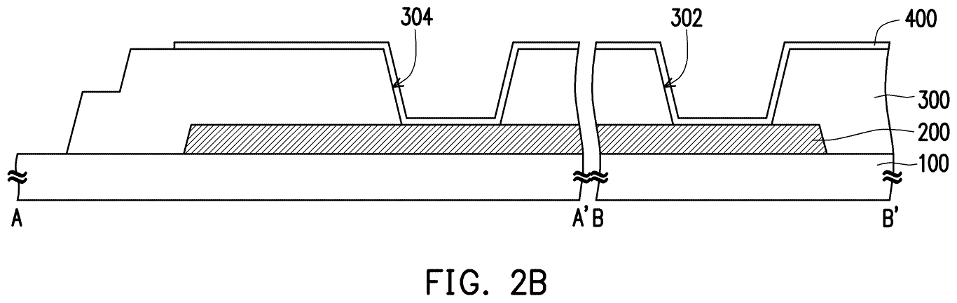

FIG. 1 is a schematic cross-sectional view of an optical panel according to an embodiment of the disclosure. FIG. 2A is a schematic top view of a substrate according to an embodiment of the disclosure. FIG. 2B is a cross-sectional schematic view taken long cross-sectional lines A-A′ and in B-B′ in FIG. 2A.

With reference to FIG. 1, an optical panel 1 includes a first substrate 10, a second substrate 20, and a display medium layer 30. The display medium layer 30 is located between the first substrate 10 and the second substrate 20. In some embodiments, the display medium layer 30 includes an electrochromic material. For instance, in a state where no current flows, the display medium layer 30 appears transparent and colorless. After current is supplied to the display medium layer 30, the display medium layer 30 changes from transparent and colorless to a non-transparent color (e.g., green).

In this embodiment, the first substrate 10 and the second substrate 20 include a same structure, and for the convenience of explanation, only one of them is shown in FIG. 2A and FIG. 2B.

With reference to FIG. 2A and FIG. 2B, each of the first substrate 10 and the second substrate 20 includes a carrier 100, a metal wire pattern 200, an insulating layer 300, and a transparent electrode 400. In order to distinguish different components in the first substrate 10 and the second substrate 20, it can also be said that the first substrate 10 includes a first carrier, a first metal wire pattern, a first insulating layer, and a first transparent electrode, and the second substrate 20 includes a second carrier, a second metal wire pattern, a second insulating layer, and a second transparent electrode. In this embodiment, as shown in FIG. 1, the display medium layer 30, the metal wire pattern 200, the insulating layer 300, and the transparent electrode 400 of the first substrate 10, and the metal wire pattern 200, the insulating layer 300, and the transparent electrode 400 of the second substrate 20 are located between the carrier 100 of the first substrate 10 and the carrier 100 of the second substrate 20. The transparent electrode 400 of the first substrate 10 and the transparent electrode 400 of the second substrate 20 overlap with each other, and the display medium layer 30 is located between the transparent electrode 400 of the first substrate 10 and the transparent electrode 400 of the second substrate 20.

The carrier 100 has an active area AA and a peripheral area BA located on at least one side of the active area AA. In this embodiment, the peripheral area BA surrounds the active area AA. The active area AA includes an edge portion A1, a transition portion A2, and the central portion A3 from outside to inside.

In some embodiments, the active area AA has a width Y1 and a length X1. The edge portion A1 is located at an edge of the active area AA. A width W3 of the edge portion A1 in a direction of the width Y1 is 5% to 30% of the width Y1, and a width W4 of the edge portion A1 in a direction of the length X1 is 5% to 30% of the width X1. A center of the central part A3 is located at a center of the active area AA, and the central portion A3 has a width Y2 in the direction of the width Y1 and a length X2 in the direction of the length X1. In some embodiments, the width Y2 of the central portion A3 is 10% to 50% of the width Y1, and the length X2 is 10% to 50% of the width X1.

In some embodiments, a material of the carrier 100 includes glass, quartz, organic polymer, or other transparent materials.

The first metal wire pattern 200 is located on the carrier 100 and extends from the peripheral area BA to the central portion of the active area AA. The metal wire pattern 200 includes a wire part 210 and a bonding part 200 electrically connected to the wire part 210. The wire part 210 extends from the peripheral area BA to the central portion A3 of the active area AA, and the bonding part 220 overlaps the peripheral area BA.

The bonding part 220 is suitable for receiving signals. For instance, a conductive clip, a wire, a flexible circuit board, or other components are bonded to the bonding part 220 to provide signals to the bonding part 220.

The wire part 210 includes first extending parts 212 extending in the direction of the length X1 of the active area AA and second extending parts 214 extending in the direction of the width Y1 of the active area AA. In this embodiment, the plurality of first extending parts 212 and the plurality of second extending parts 214 are connected to each other to form a network. In some embodiments, one of the first extending parts 212 is located in the central portion A3 of the active area AA, and another first extending part 212 is located in the edge portion A1 of the active area AA. The second extending part 214 extends from the edge portion A1 into the central portion A3.

In some embodiments, the metal wire pattern 200 has a single-layer or multi-layer structure, and a material thereof includes gold, silver, copper, aluminum, molybdenum, titanium, tantalum, other metals or alloys of the foregoing metals, or other suitable metal materials.

The insulating layer 300 is located on the carrier 100 and the metal wire pattern 200 and has a first through hole 302 overlapping the central portion A3 of the active area AA and a second through hole 304 overlapping the edge portion A1 of the active area AA. The numbers of the first through hole 302 and the second through hole 304 may be adjusted according to actual needs. A portion of the metal wire pattern 200 is located below the first through hole 302, and another portion of the metal wire pattern 200 is located below the second through hole 304. In this embodiment, one of the first extending parts 212 is located below the first through hole 302, and another first extending part 212 is located below the second through hole 304.

In some embodiments, the insulating layer 300 exposes the bonding part 220 of the metal wire pattern 200, so that the conductive clip, the wire, the flexible circuit board, or other components may be bonded to the bonding part 220. For instance, an external component may directly contact the bonding part 220 or may be connected to the bonding part 220 through conductive connection such as solder and conductive glue.

In some embodiments, a material of the insulating layer 300 includes silicon oxide, silicon nitride, silicon oxynitride, aluminum oxide, hafnium oxide, an organic insulating material, or other suitable materials.

The transparent electrode 400 is located on the insulating layer 300 and overlaps the active area AA entirely. In some embodiments, an area of the active area AA is defined by an area of the transparent electrode 400. The transparent electrode 400 is electrically connected to the metal wire pattern 200. For instance, the transparent electrode 400 is electrically connected to the metal wire pattern 200 through the first through hole 302 and the second through hole 304. Through the arrangement of the first through hole 302, a resistance from the bonding part 220 to the transparent electrode 400 on the central portion A3 may be lowered. Therefore, after power is supplied to the bonding part 220, the display medium layer 30 on the central portion A3 and the display medium layer 30 on the edge portion A1 may receive current in a similar time, so that a color change time of the display medium layer 30 is shortened. To be more specific, through the arrangement of the first through hole 302 and the second through hole 304, after power is supplied to the bonding part 220, the display medium layer 30 may change color from the edge portion A1 and from the central portion A3 almost simultaneously. However, if only the second through hole 304 is provided without the first through hole 302, the display medium layer 30 may only start to change color from the edge portion A1.

In some embodiments, a material of the transparent electrode 100 includes indium tin oxide, indium zinc oxide, aluminum tin oxide, aluminum zinc oxide, indium gallium zinc oxide, a stacked layer of at least two of the foregoing, or other suitable materials.

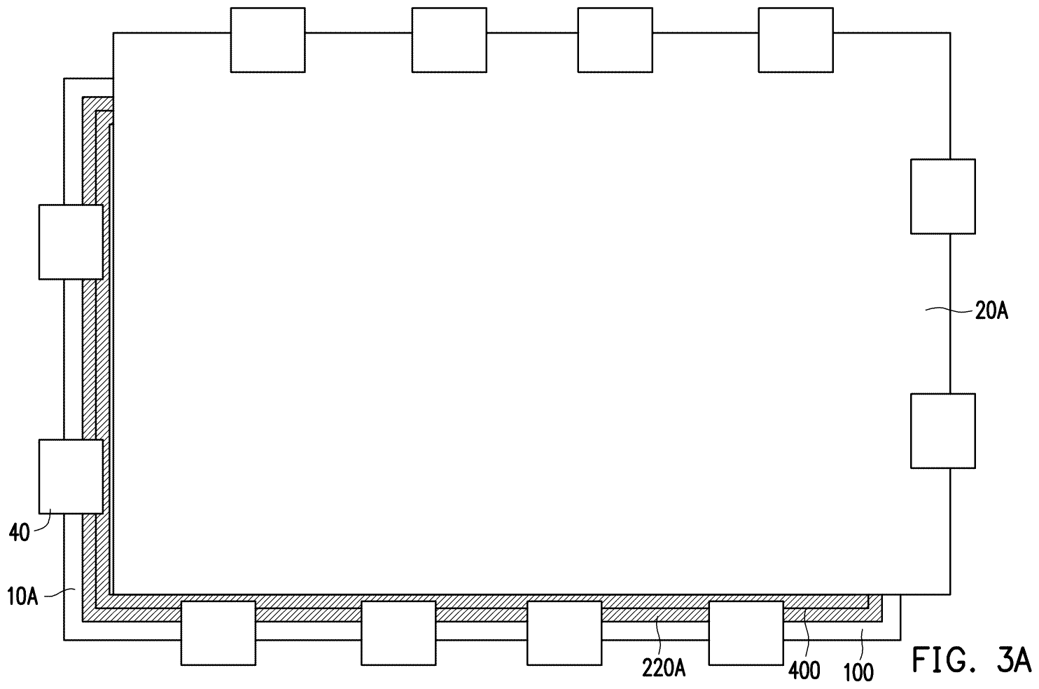

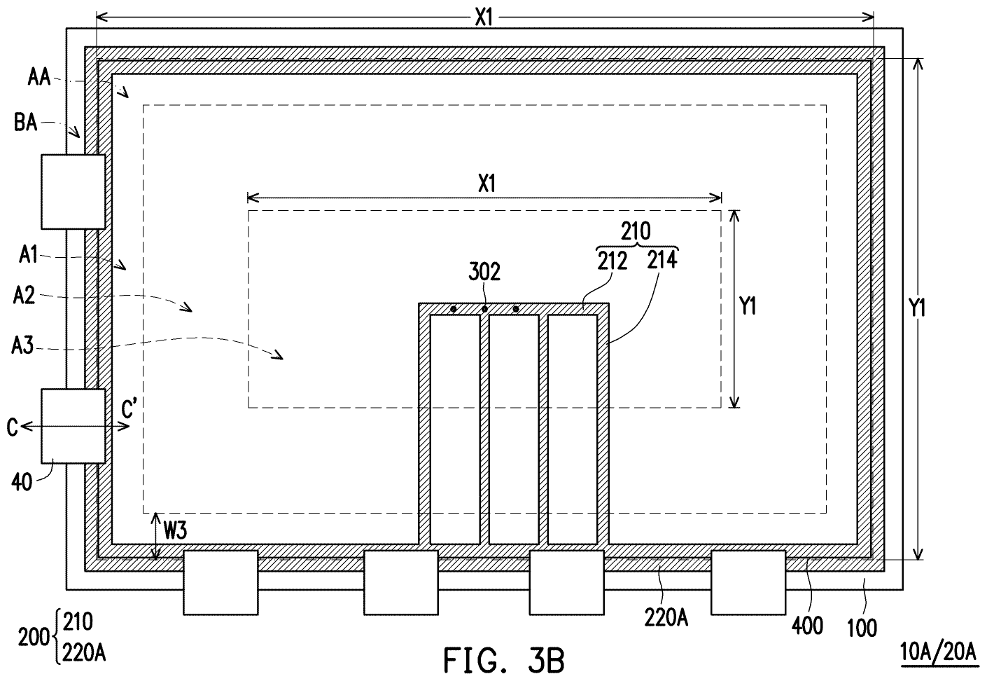

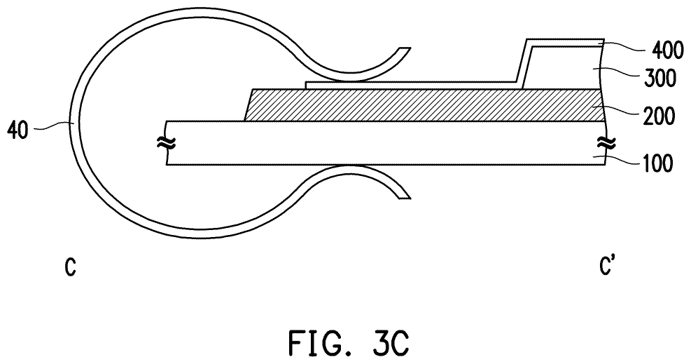

FIG. 3A is a schematic top view of an optical panel according to an embodiment of the disclosure FIG. 3B is a schematic top view of a substrate according to an embodiment of the disclosure. FIG. 3C is a cross-sectional schematic view taken long a cross-sectional line C-C′ in FIG. 3B. In this embodiment, the first substrate 10A and the second substrate 20A include the same structure, and for the convenience of explanation, only one of them is shown in FIG. 3B.

It should be mentioned herein that the reference numerals and part of the content provided in the embodiments shown in FIG. 1 to FIG. 2B are applied in the embodiments shown in FIG. 3A to FIG. 3C, where the same or similar reference numerals serve to denote the same or similar components, and the description of the same technical content is omitted. Please refer to the descriptions of the previous embodiments for the omitted part, which will not be repeated hereinafter.

With reference to FIG. 3A and FIG. 3C, each of the first substrate 10A and the second substrate 20A includes the carrier 100, the metal wire pattern 200, the insulating layer 300, and the transparent electrode 400.

In this embodiment, the first metal wire pattern 200 is located on the carrier 100 and extends from the peripheral area BA to the central portion of the active area AA. The metal wire pattern 200 includes the wire part 210 and a bonding part 200A electrically connected to the wire part 210. The wire part 210 extends from the peripheral area BA to the central portion A3 of the active area AA, and the bonding part 220A overlaps the peripheral area BA.

In this embodiment, the bonding part 220A is annular and contacts an edge of the transparent electrode 400. For instance, an edge of the insulating layer 300 is located on or inside the bonding part 220A, and the transparent electrode 400 extends from a top surface of the insulating layer 300 along the edge of the insulating layer 300 to the bonding part 220A.

A plurality of conductive clips 40 are clamped on the bonding part 220A. In this embodiment, the conductive clips 40 contact the transparent electrode 400 on the bonding part 220A.

In this embodiment, through the arrangement of the first through hole 302, a resistance from the bonding part 220A to the transparent electrode 400 on the central portion A3 may be lowered. Therefore, after power is supplied to the bonding part 220A, the display medium layer on the central portion A3 and the display medium layer on the edge portion A1 may receive current in a similar time, so that the color change time of the display medium layer is shortened. To be more specific, through the arrangement of the first through hole 302 and the annular bonding part 220A, the display medium layer may change color from the edge portion A1 and the central portion A3 almost simultaneously.

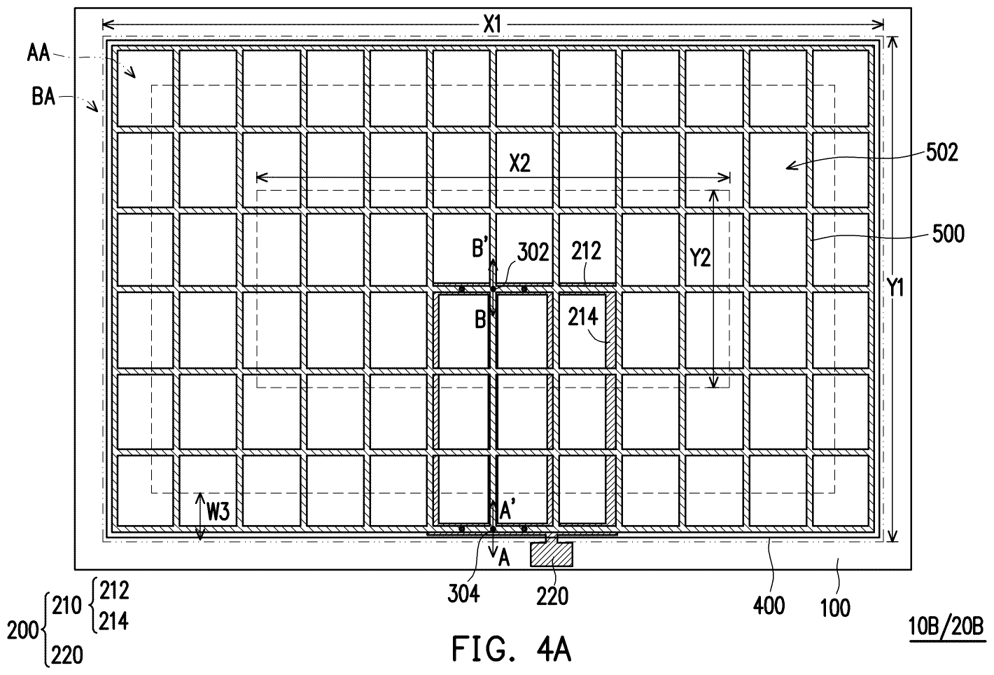

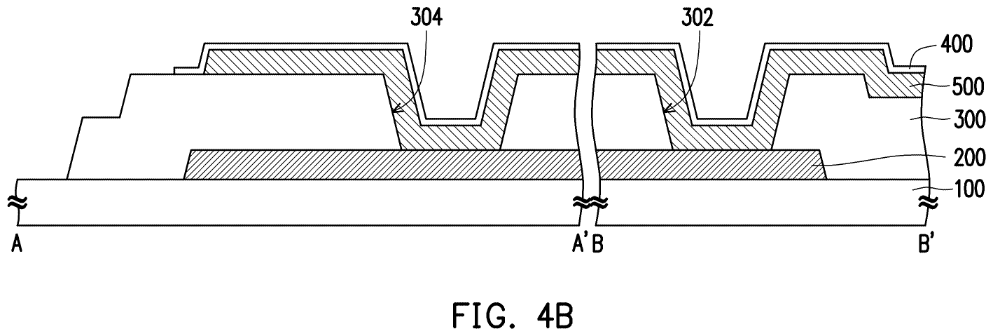

FIG. 4A is a schematic top view of a substrate according to an embodiment of the disclosure. FIG. 4B is a cross-sectional schematic view taken long cross-sectional lines A-A′ and in B-B′ in FIG. 4A. In this embodiment, a first substrate 10B and a second substrate 20B include the same structure, and for the convenience of explanation, only one of them is shown in FIG. 4A.

It should be mentioned herein that the reference numerals and part of the content provided in the embodiments shown in FIG. 1 to FIG. 2B are applied in the embodiments shown in FIG. 4A to FIG. 4B, where the same or similar reference numerals serve to denote the same or similar components, and the description of the same technical content is omitted. Please refer to the descriptions of the previous embodiments for the omitted part, which will not be repeated hereinafter.

With reference to FIG. 4A and FIG. 4B, each of the first substrate 10B and the second substrate 20B includes the carrier 100, the metal wire pattern 200, the insulating layer 300, a metal mesh 500, and the transparent electrode 400.

The metal mesh 500 is located on the insulating layer 300 and located between the insulating layer 300 and the transparent electrode 400. In this embodiment, the metal mesh 500 is located on the edge portion A1, the transition portion A2, and the central portion A3 and contacts the metal wire pattern 200 through the first through hole 302 and the second through hole 304. In this embodiment, the metal mesh 500 includes a plurality of openings 502 with a same size, but the disclosure is not limited thereto. In other embodiments, the metal mesh 500 includes a plurality of openings 502 of varying sizes. In some embodiments, the width (and thus length) of the openings 502 is less than 5 centimeters.

In some embodiments, the metal mesh 500 has a single-layer or multi-layer structure, and a material thereof includes gold, silver, copper, aluminum, molybdenum, titanium, tantalum, other metals or alloys of the foregoing metals, or other suitable metal materials.

The transparent electrode 400 covers the metal mesh 500. The transparent electrode 400 is filled in the openings 502 of the metal mesh 500.

In this embodiment, the metal mesh 500 may improve uniformity of voltage distribution on the transparent electrode 400, so that a color change time difference of the display medium layer on the edge portion A1, the transition portion A2, and the central portion A3 is reduced.

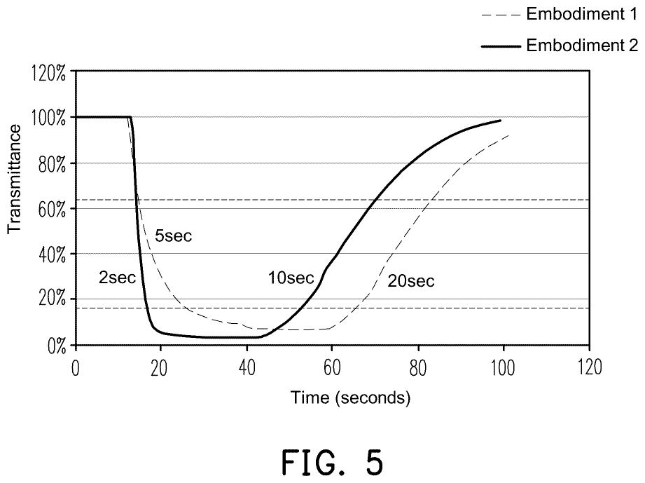

FIG. 5 is a graph of transmittance versus time of an optical panel according to some embodiments of the disclosure. In FIG. 5, the first substrate and the second substrate in the optical panel of Embodiment 1 have similar structures to the first substrate and the second substrate in the optical panel of Embodiment 2. The difference is that the first substrate and the second substrate in the optical panel of Embodiment 2 have a metal mesh (as shown in FIG. 4A and FIG. 4B), while the first substrate and the second substrate of the optical panel of Embodiment 1 do not have a metal mesh.

It can be seen from FIG. 5 that by arranging the metal mesh in the first substrate and the second substrate, the time for the optical panel to change from transparent to non-transparent after power is turned on may be shortened, and the time for the optical panel to transform from non-transparent to transparent may also be shortened.

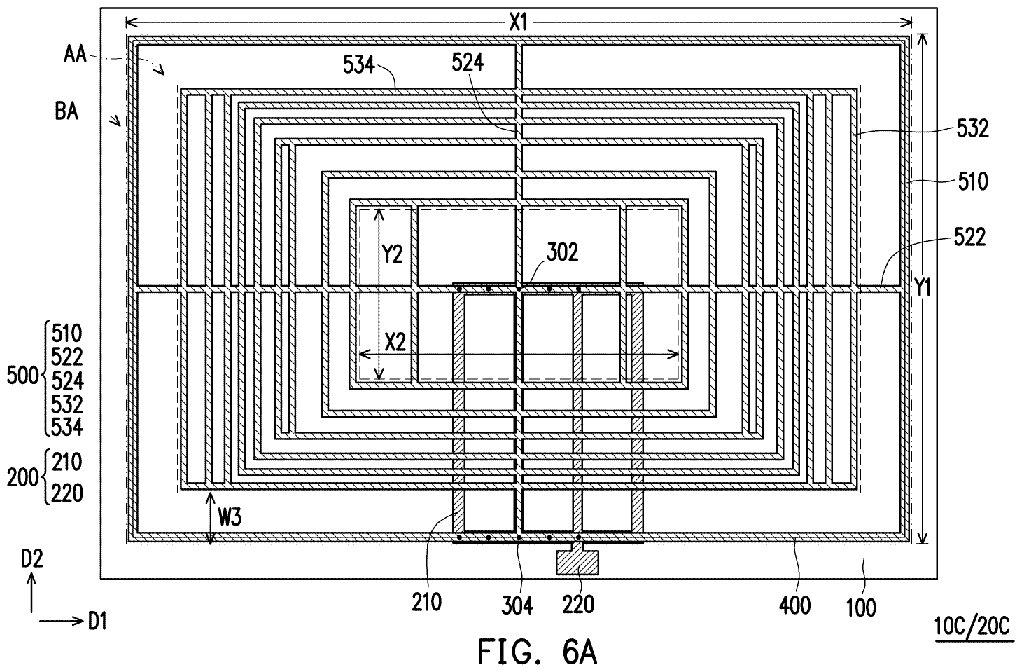

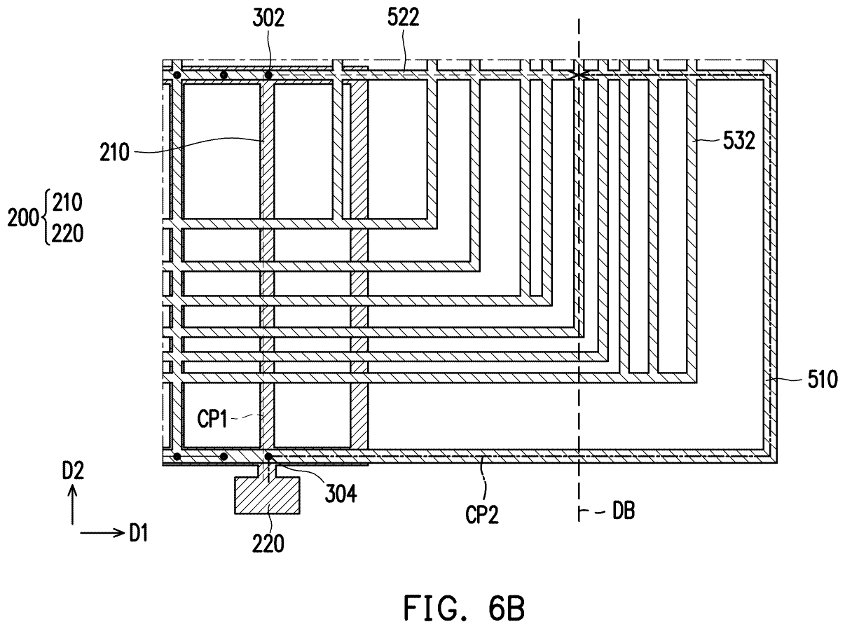

FIG. 6A is a schematic top view of a substrate according to an embodiment of the disclosure. FIG. 6B is a partially enlarged schematic view of the substrate of FIG. 6A. In this embodiment, a first substrate 10C and a second substrate 20C include the same structure, and for the convenience of explanation, only one of them is shown in FIG. 6A.

It should be mentioned herein that the reference numerals and part of the content provided in the embodiments shown in FIG. 4A to FIG. 4B are applied in the embodiments shown in FIG. 6A to FIG. 6B, where the same or similar reference numerals serve to denote the same or similar components, and the description of the same technical content is omitted. Please refer to the descriptions of the previous embodiments for the omitted part, which will not be repeated hereinafter.

With reference to FIG. 6A, in this embodiment, the metal mesh 500 includes a plurality of openings of different sizes, and the metal mesh 500 on the active area AA has different densities in different areas. For instance, the density of the metal mesh 500 on the edge portion A1 and the central portion A3 is less than the density of the metal mesh 500 on the transition portion A2.

In this embodiment, the metal mesh 500 includes an outer frame part 510, a first conductive part 522, a second conductive part 524, first branch parts 532, and second branch parts 534. The outer frame part 510 is located on the edge portion A1 of the active area AA and is an outermost portion of the metal mesh 500. In this embodiment, the outer frame part 510 is a rectangular frame.

The first conductive part 522 spans the edge portion A1, the transition portion A2, and the central portion A3. Two ends of the first conductive part 522 are connected to the outer frame part 510. In this embodiment, the first conductive part 522 extends in a first direction D1, where the first direction D1 is parallel to the length X1 of the active area AA. In this embodiment, the first conductive part 522 is a straight line, but the disclosure is not limited thereto. In other embodiments, the first conductive part 522 is an arc.

The second conductive part 524 is interlaced with the first conductive part 522 and spans the edge portion A1, the transition portion A2, and the central portion A3. Two ends of the second conductive part 524 are connected to the outer frame part 510. In this embodiment, the second conductive part 524 extends in a second direction D2, where the second direction D2 is parallel to the width Y1 of the active area AA. In this embodiment, the second conductive part 524 is a straight line, but the disclosure is not limited thereto. In other embodiments, the second conductive part 524 is an arc. In this embodiment, an interlaced position of the first conductive part 522 and the second conductive part 524 is located on the central portion A3.

The plurality of first branch parts 532 are interlaced with the first conductive part 522 and distributed on both sides of the second conductive part 524. The first conductive part 522 passes through the first branch parts 532. The first branch parts 532 are arranged in the extending direction (e.g., the first direction D1) of the first conductive part 522. The first branch parts 532 extend in the second direction D2. In this embodiment, the first branch parts 532 are straight lines, but the disclosure is not limited thereto. In other embodiments, the first branch parts 532 are arcs. In some embodiments, the density of the first branch parts 532 on the edge portion A1 and the central portion A3 is less than the density of the first branch parts 532 on the transition portion A2. In some embodiments, the first branch parts 532 are not provided on the edge portion A1 and/or the central portion A3.

The plurality of second branch parts 534 are interlaced with the second conductive part 524 and distributed on both sides of the first conductive part 522. The second conductive part 524 passes through the second branch parts 534. The second branch parts 534 are arranged in the extending direction (e.g., the second direction D2) of the second conductive part 524. The second branch parts 534 extend in the first direction D1. In this embodiment, the second branch parts 534 are straight lines, but the disclosure is not limited thereto. In other embodiments, the second branch parts 534 are arcs. In some embodiments, the density of the second branch parts 534 on the edge portion A1 and the central portion A3 is less than the density of the second branch parts 534 on the transition portion A2. In some embodiments, the second branch parts 534 are not provided on the edge portion A1 and/or the central portion A3.

In this embodiment, two ends of each of the first branch parts 532 are connected to two second branch parts 534, and two ends of each of the second branch parts 534 are connected to two first branch parts 532.

In some embodiments, a wire diameter of a metal wire of the outer frame part 510 is greater than a wire diameter of a metal wire of each of the first conductive part 522, the second conductive part 524, the first branch parts 532, and the second branch parts 534. That is, under the condition of the same length, the metal wire of the outer frame part 510 has a lower resistance.

In this embodiment, by adjusting the density distribution of the metal mesh 500, the resistance difference between the bonding part 220 of the metal wire pattern 200 and different positions on the transparent electrode 400 may be reduced. In this way, the problem of inconsistent color change time of the display medium layer at different positions due to different resistance is improved.

With reference to FIG. 6B, in some embodiments, the location with the highest density on the metal mesh 500 is calculated by measuring the resistance. For instance, an analog current flows through a first circuit CP1 and a second circuit CP2. The first circuit CP1 runs from the bonding part 220 of the metal wire pattern 200 through the first through hole 302 in the central portion A3 to the dummy boundary line DB on the first conductive part 522. The second circuit CP2 runs from the bonding part 220 of the metal wire pattern 200 through the second through hole 304 at the edge portion A1 to the outer frame part 510 and then reaches the dummy boundary line DB on the first conductive part 522 from outer frame part 510.

In some embodiments, a resistance of the first circuit CP1 is equal to a resistance of the second circuit CP2. That is, the resistance from the bonding part 220 of the metal wire pattern 200 through the first through hole 302 in the central portion A3 to the dummy boundary line DB on the first conductive part 522 is equal to the resistance from the bonding part 220 of the metal wire pattern 200 through the second through hole 304 in the edge portion A1 and the outer frame part 510 to the dummy boundary line DB on the first conductive part 522. The position of the dummy boundary line DB is obtained by measuring the resistance values of different circuits. The first branch parts 532 have the highest distribution density in the area close to the dummy boundary line DB and have a decreasing distribution density from the dummy boundary line DB toward the center of the active area AA and the edge of the active area AA.

In some embodiments, a similar method may be used to obtain the position where the second branch parts 534 have the highest distribution density.

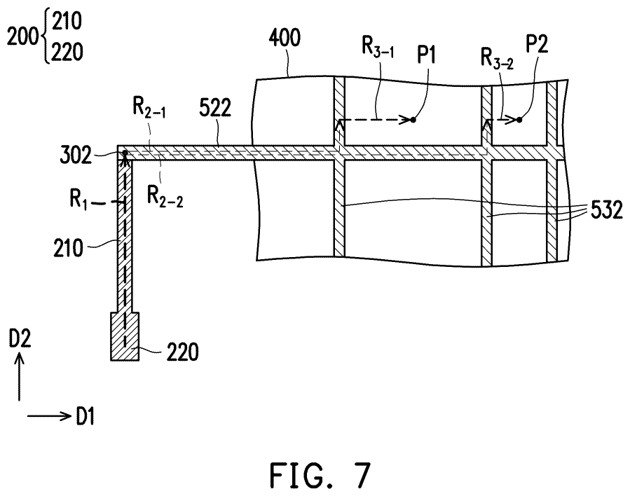

FIG. 7 is a schematic top view of a metal mesh design method according to an embodiment of the disclosure. For instance, the method shown in FIG. 7 may be used to design the metal mesh 500 shown in FIG. 6A and FIG. 6B.

A spacing between the first branch parts 532 of the metal mesh 500 changes with a distance between the first branch parts 532 and the dummy boundary line DB (with reference to FIG. 6B). The spacing distribution of the first branch parts 532 may be obtained by the method shown in FIG. 7. With reference to FIG. 7, in the area between two adjacent first branch parts 532, a position P1 having a maximum resistance from the bonding part 220 to the transparent electrode 400 is selected. In the area between two other adjacent first branch parts 532, a position P2 having the maximum resistance from the bonding part 220 to the transparent electrode 400 is selected. A total resistance value from the bonding part 220 of the metal wire pattern 200 to the position P1 is equal to the total resistance value from the bonding part 220 of the metal wire pattern 200 to the position P2.

To be specific, in this embodiment, the total resistance value from the bonding part 220 of the metal wire pattern 200 to the position P1 includes a metal resistor R_{L1} (as shown in FIG. 7, a resistance R₁ from the bonding part 220 to the corresponding first through hole 302 plus a resistance R₂₋₁ from the corresponding first through hole 302 to the position of the metal mesh 500 closest to the position P1) plus a transparent electrode resistor R₃₋₁ (as shown in FIG. 7, a resistance R₃₋₁ from the position of the metal mesh 500 closest to the position P1 to the position P1). The total resistance value from the bonding part 220 of the metal wire pattern 200 to the position P2 includes a metal resistor R_{L2} (as shown in FIG. 7, the resistance R₁ from the bonding part 220 to the corresponding first through hole 302 plus a resistance R₂₋₂ from the corresponding first through hole 302 to the position of the metal mesh 500 closest to the position P2) plus a transparent electrode resistor R₃₋₂ (as shown in FIG. 7, a resistance R₃₋₂ from the position of the metal mesh 500 closest to the position P2 to the position P2). In this embodiment, a sum of the metal resistor R_{L1} and the transparent electrode resistor R₃₋₁ is equal to a sum of the metal resistor R_{L2} and the transparent electrode resistor R₃₋₂. The metal resistor R_{L1} is less than the metal resistor R_{L2}, and the transparent electrode resistor R₃₋₁ is greater than the transparent electrode resistor R₃₋₂.

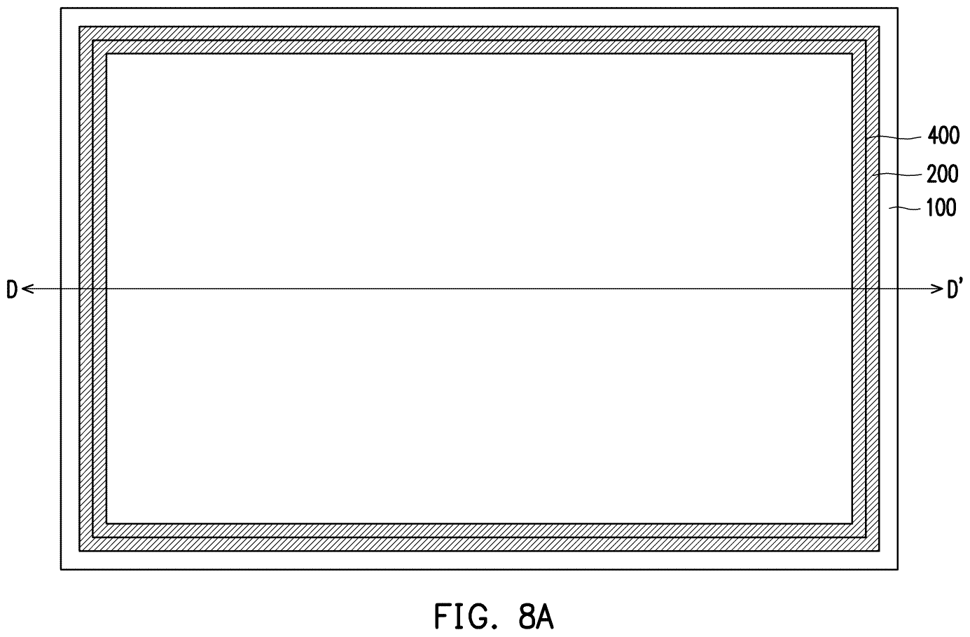

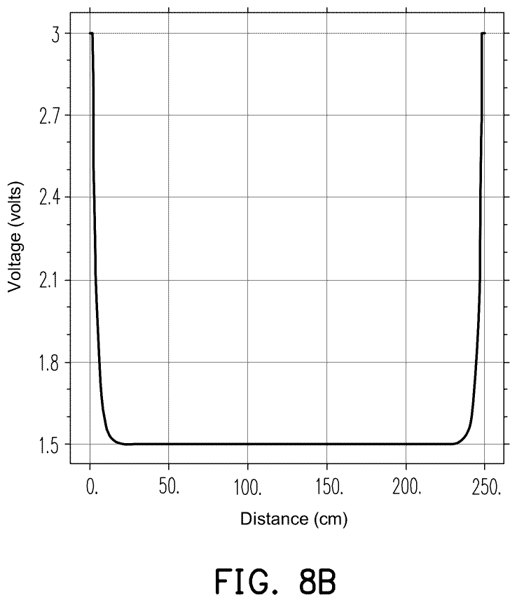

FIG. 8A is a schematic top view of a substrate according to a comparative example of the disclosure. FIG. 8B is a graph of voltage distribution of a transparent electrode of the substrate of FIG. 8A. FIG. 8B corresponds to the position of a line D-D′ in FIG. 8A.

With reference to FIG. 8A and FIG. 8B, in the comparative example, the metal wire pattern 200 is ring-shaped and overlaps the edge of the transparent electrode 400. The metal wire pattern 200 does not extend into the central portion of the active area. As can be seen from FIG. 8B, when a voltage is applied to the substrate, the voltage on the transparent electrode 400 decreases as it moves away from the metal wire pattern 200. Therefore, in order to maintain uniformity of voltage distribution, the size of the opening 502 of the metal mesh 500 shown in FIG. 4A is preferably less than 5 cm, so that the voltage drop can be lowered (for example, controlling the voltage drop within 20%).

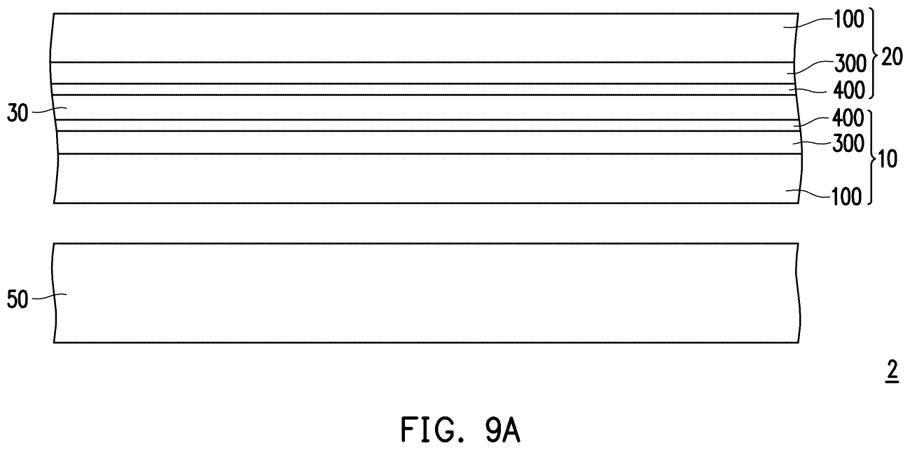

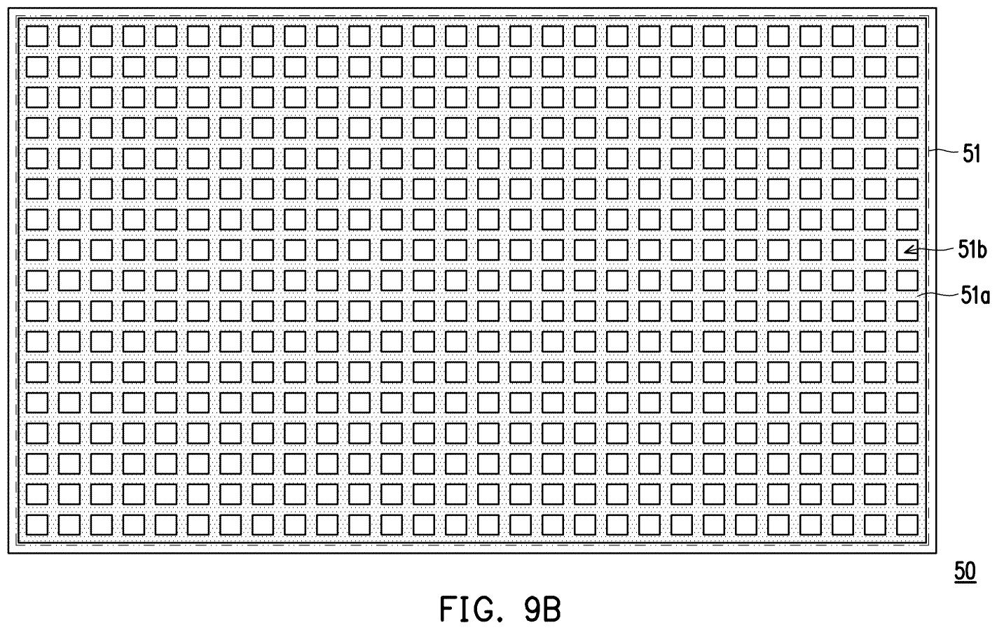

FIG. 9A is a schematic cross-sectional view of an optical panel according to an embodiment of the disclosure. FIG. 9B is a schematic top view of a transmissive display panel of FIG. 9A. In FIG. 9A, the structures of the first substrate 10 and the second substrate 20 may adopt the structures described in any of the above embodiments, so description thereof is not repeated herein.

With reference to FIG. 9A and FIG. 9B, an optical panel 2 includes the first substrate 10, the second substrate 20, the display medium layer 30, and a transmissive display panel 50. The display medium layer 30 is located between the first substrate 10 and the second substrate 20. The transmissive display panel 50 overlaps the first substrate 10, the second substrate 20, and the display medium layer 30.

The transmissive display panel 50 has a display area 51. The display area 51 has a non-transmissive area 51a and a transmissive area 51b. The transmissive area 51a has a wire, a light-emitting diode, an active element, a passive element, and other non-transparent components. The transmissive area 51b is a transparent area. In this embodiment, the metal structures (such as the metal wire pattern and the metal mesh) in the first substrate 10 and the second substrate 20 overlap in the non-transmissive area 51a, and in this way, the influence of the first substrate 10 and the second substrate 20 on the transmittance of the optical panel 2 is lowered.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An optical panel, comprising:
a first substrate, comprising:
a first carrier having an active area and a peripheral area located on at least one side of the active area;
a first metal wire pattern located on the first carrier and extending from the peripheral area to a central portion of the active area;
a first insulating layer located on the first carrier and the first metal wire pattern and having a first through hole overlapping the central portion of the active area, wherein a portion of the first metal wire pattern is located below the first through hole; and
a first transparent electrode located on the first insulating layer and overlapping the active area entirely, wherein the first transparent electrode is electrically connected to the first metal wire pattern; and
a second substrate, comprising:
a second carrier; and
a second transparent electrode located between the second carrier and the first carrier and overlapping the first transparent electrode; and
a display medium layer located between the first transparent electrode and the second transparent electrode.

2. The optical panel according to claim 1, wherein the first substrate further comprises a metal mesh located on the first insulating layer and contacting the first metal wire pattern through the first through hole, wherein the first transparent electrode covers the metal mesh.

3. The optical panel according to claim 2, further comprising:
a transmissive display panel overlapping the first substrate, the second substrate, and the display medium layer, wherein the transmissive display panel comprises a transmissive area and a non-transmissive area, and the first metal wire pattern and the metal mesh overlap the non-transmissive area.

4. The optical panel according to claim 2, wherein the active area comprises an edge portion, a transition portion, and the central portion from outside to inside, wherein a density of the metal mesh on the edge portion and the central portion is less than a density of the metal mesh on the transition portion.

5. The optical panel according to claim 2, wherein the metal mesh comprises:
an outer frame part located on the edge portion and is an outermost portion of the metal mesh;
a first conductive part connected to the outer frame part and spanning the edge portion, the transition portion, and the central portion; and
a plurality of first branch parts interlaced with the first conductive part, wherein the first conductive part passes through the first branch parts.

6. The optical panel according to claim 5, wherein the first insulating layer further comprises a second through hole overlapping the edge portion of the active area, and another portion of the first metal wire pattern is located below the second through hole, wherein a resistance on a dummy boundary line from the first metal wire pattern through the first through hole to the first conductive part is equal to a resistance on the dummy boundary line from the first metal wire pattern through the second through hole and the outer frame part to the first conductive part, the first branch parts have a highest distribution density in an area close to the dummy boundary line.

7. The optical panel according to claim 2, wherein the metal mesh comprises a plurality of openings of different sizes.

8. The optical panel according to claim 1, wherein the first insulating layer further comprises a second through hole overlapping the edge portion of the active area, and another portion of the first metal wire pattern is located below the second through hole.

9. The optical panel according to claim 1, wherein the first metal wire pattern comprises a wire part and a bonding part electrically connected to the wire part, the wire part extends from the peripheral area to the central portion of the active area, and the bonding part overlaps the peripheral area.

10. The optical panel according to claim 9, wherein the bonding part is annular and contacts an edge of the first transparent electrode.

11. The optical panel according to claim 9, further comprising:
a conductive clip clamped on the bonding part.
